(19) United States
(12) Patent Application Publication
(10) Pub. No.: US 2018/0080756 A1
(43) Pub. Date: Mar. 22, 2018

(54) MEASUREMENT TOOL AND METHOD FOR MEASURING THICKNESS OF EVAPORATED FILM OF LARGE-SIZED SUBSTRATE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Fengjie Zhang, Beijing (CN); Shupeng Guo, Beijing (CN); Xiaoyun Liu, Beijing (CN)

(21) Appl. No.: 15/520,406

(22) PCT Filed: Aug. 2, 2016
(86) PCT No.: PCT/CN2016/092835

§ 371 Date: Apr. 19, 2017

(30) Foreign Application Priority Data
Jan. 5, 2016 (CN) 201610005253.7

(51) Int. Cl. G01B 11/06; C23C 14/54

(52) U.S. Cl. CPC G01B 11/0683; C23C 14/542

(57) ABSTRACT

The present disclosure relates to a measurement tool, for measuring the thickness of an evaporated film at a particular position on a large-sized substrate. The measurement tool includes: a measurement part, having at least one measurement surface onto which at least one sampling substrate sheet is positional and fixable; and a support part connected with the support part and configured to be supportable on an edge frame of a mask so as to place the measurement part in an inside of the edge frame of the mask through the support part. The present disclosure also relates to a method of measuring a thickness of an evaporated film of a large-sized substrate by using the above measurement tool.

### CROSS-REFERENCE TO RELATED APPLICATION

The present application claims the benefit of Chinese Patent Application No. 201610005253.7, entitled “measurement tool and method for measuring thickness of evaporated film of large-sized substrate” and filed on Jan. 5, 2016, the entire disclosure of which is incorporated herein by reference.

### BACKGROUND

### Technical Field

The present disclosure relates to the technique field of measurement tools, and particularly, to a tool for measuring a thickness of an evaporated film of a large-sized substrate and a method of measuring a thickness of an evaporated film of a large-sized substrate.

### Description of the Related Art

Vacuum evaporation is a common film evaporation technology, in which a substance used to form a film is placed in vacuum so that it vaporizes or sublimes so as to form a film on a substrate. Before batch production of an evaporated film, an evaporation source of an evaporation apparatus needs to be adjusted for forming a desired film on the substrate. For a large-sized substrate, adjustment of the film evaporation apparatus may encounter some problems; for example, since the substrate has a larger size, it is rather inconvenient for an operator to perform adjustment operations, and it is required to evaporate a film on the whole substrate as a sample during adjustment; in case that it is desired to evaporate a plurality of layers of films on the substrate, it is required to provide one substrate as an adjustment sample for measuring the thickness of each of the layers of films, which will result in a higher cost for adjustment due to the larger size and high cost of the substrate. In addition, it is required to obtain a uniform thickness for the evaporated film on the whole of the large-sized substrate, thus there will be many measurement points during adjustment, thereby resulting in a longer measurement time period.

### SUMMARY

According to an aspect of the present disclosure, there is provided a measurement tool for measuring a thickness of an evaporated film of a large-sized substrate, and the measurement tool comprises: a measurement part, having at least one measurement surface onto which at least one sampling substrate sheet is positional and fixable; and a support part connected with the support part and configured to be supportable on an edge frame of a mask so as to place the measurement part on an inner side of the edge frame of the mask through the support part.

In one embodiment, the at least one measurement surface has graduations configured to indicate a position of the at least one sampling substrate sheet on the at least one measurement surface, the position of the at least one sampling substrate sheet on the at least one measurement surface corresponding to a position of a measurement point on the large-sized substrate.

In one embodiment, the measurement part comprises a rectangular sheet body, an upper surface and/or a lower surface of the sheet body forms the at least one measurement surface, and the graduations are distributed on the at least one measurement surface in a length direction of the measurement part, such that the at least one sampling substrate sheet is allowed to be distributed and arranged alongside the graduations.

In one embodiment, the measurement part is in a shape of a triangular prism, a side surface of the triangular prism forms the at least one measurement surface, and the graduations are distributed on the at least one measurement surface in an axial direction of the triangular prism, such that the at least one sampling substrate sheet is allowed to be distributed and arranged alongside the graduations.

In one embodiment, the measurement part is provided with a groove located alongside the graduations and configured to receive the at least one sampling substrate sheet.

In one embodiment, the measurement part is made of aluminum.

In one embodiment, the support part has an elongated shape, is fixed on the upper surface or the lower surface of the measurement part, and has a length larger than lengths of the measurement part and the large-sized substrate.

In one embodiment, the support part comprises two elongated support bodies connected to the upper surface or the lower surface of the measurement part through an adhesive or screw connection.

In one embodiment, the support part is fixed on two ends of the measurement part and is configured to be rotatably connected onto the frame of the mask, such that the measurement tool can rotate the measurement part without being separated from the mask, thereby films can be evaporated on sampling substrate sheets located on different surfaces of the measurement part.

In one embodiment, the measurement tool comprises a plurality of the measurement parts.

According to another aspect of the present disclosure, there is further provided a method of measuring a thickness of an evaporated film of a large-sized substrate by using the above measurement tool, and the method comprises steps of:

fixing at least one sampling substrate sheet at a prescribed position on the measurement surface of the measurement part according to the graduations of the measurement part, the prescribed position corresponding to a position of a measurement point of the large-sized substrate; placing the measurement part carrying thereon a sampling substrate sheet on an inner side of the frame of the mask through the support part, then placing the mask carrying thereon the measurement part within a film formation region of an evaporation source of a film evaporation apparatus, such that the sampling substrate sheet on at least one measurement surface of the measurement part faces the evaporation source so as to be evaporated with a film by the evaporation source; and after evaporating the film, taking off the measurement tool, removing the sampling substrate sheet from the measurement part, and measuring the thickness of the evaporated film of the sampling substrate sheet, thereby obtaining the thickness of the evaporated film of the large-sized substrate at the measurement point.

In one embodiment, the step of evaporating the film onto the sampling substrate sheet comprises: after evaporating the film onto the sampling substrate sheet which is located on one measurement surface of the measurement part, rotating the measurement part so as for enabling another measurement surface to face the evaporation source, and evaporating a film onto the sampling substrate sheet which is located on the another measurement surface.

### BRIEF DESCRIPTION OF THE DRAWINGS

FIG. 1 is a partially perspective view of a measurement tool according to an embodiment of the present disclosure.

FIG. 2 is a partially perspective view of a measurement tool according to an embodiment of the present disclosure, which is connected onto a mask.

FIG. 3 is a partially perspective view of a measurement tool according to another embodiment of the present disclosure.

FIG. 4 is a partially perspective view of a measurement tool according to a further embodiment of the present disclosure, which is connected onto a mask.

FIG. 5 is a perspective view of a plurality of measurement tools according to a still further embodiment of the present disclosure, which are connected onto a mask.

FIG. 6 is a schematic diagram showing a measurement tool according to an embodiment of the present disclosure, which is connected onto a mask and on which a film has been evaporated by an evaporation source.

### DETAILED DESCRIPTION OF THE EMBODIMENTS

Technique solutions in embodiments of the present disclosure will be described clearly and completely hereinafter in detail with reference to the attached drawings in the embodiments. Obviously, the described embodiments are only some of embodiments of the present disclosure, instead of all of the embodiments of the present disclosure. For those skilled in the art, all other embodiments achieved by referring to the following embodiments of the present disclosure without involving any inventive steps fall into the scope of the present disclosure.

According to a general inventive concept of the present disclosure, there is provided a measurement tool for measuring a thickness of an evaporated film of a large-sized substrate, and the measurement tool comprises: a measurement part, having at least one measurement surface onto which at least one sampling substrate sheet is positional and fixable; and a support part, connected with the support part and configured to be supportable on an edge frame of a mask so as to place the measurement part on an inner side of the edge frame of the mask through the support part. Under same film evaporation conditions, the measurement tool according to embodiments of the present disclosure may obtain the thickness at a measurement point on the large-sized substrate by measuring the thickness of a film on the sampling substrate sheet (the position of the sampling substrate sheet on the measurement surface corresponds to the position of the measurement point on the large-sized substrate), thereby greatly saving measurement cost and shortening measurement time.

Further, in the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

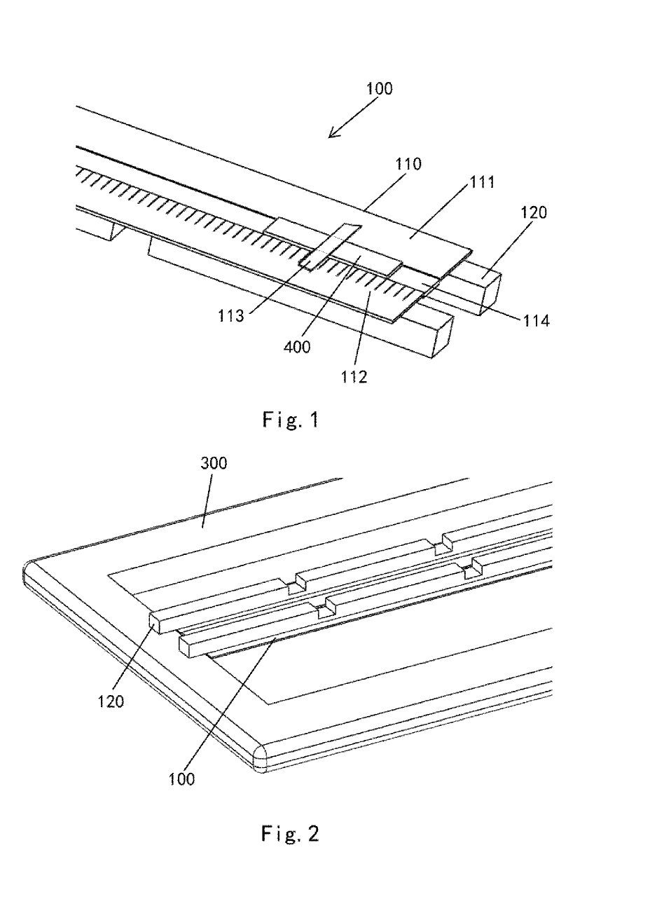

FIG. 1 shows a measurement tool 100 according to an embodiment of the present disclosure, comprising a measurement part 110, which may be made of a heat resistant material, such as aluminum for example. The measurement part 110 is used to fix at least one sampling substrate sheet 400 of a substrate onto a particular position on the measurement part 110 by using fixation means such as adhesive 113. Optionally, the adhesive 113 may be a heat resistant adhesive tape or glue. The measurement part 110 is an elongated (i.e., rectangular) sheet body, graduations are distributed on an upper surface 111 of the measurement part 110 in a length direction of the measurement part 110, and the sampling substrate sheet 400 may be arranged a particular position alongside the graduations. Optionally, a groove 114 is provided alongside the graduations 112 and is configured to receive the sampling substrate sheet 400, the groove 114 has a depth designed such that when the sampling substrate sheet 400 is placed into the groove 114, an upper surface of the sampling substrate sheet 400 is flush with the upper surface 111 of the measurement part 110. The length of the measurement part 110 is equal to that of the large-sized substrate, such that the measurement part 110 can be just placed inside a frame of a mask 300. A support part 120 (for example, the support part comprises two support bodies) is provided on a lower surface of the measurement part 110. Optionally, the support part 120 is fixed onto the lower surface of the measurement part 110 by using a screw, adhesive or the like, and accordingly, the support part 120 is provided with a groove to receive a head of the screw, thereby avoiding the head of the screw from protruding outside a supporting surface. The support part 120 may be also made of a heat resistant material, for example, a heat resistant metal. The support part 120 is in a shape of an elongated bar and has a length slightly larger than that of the measurement part 110, so that an end of the support part 120 may extend beyond the measurement part 110, thereby the extended end can be connected onto an edge frame of the mask 300.

When it is ready for evaporating a film on the sampling substrate sheet, the sampling substrate sheets 400 are placed at particular positions in the groove of the measurement part 110—the particular positions correspond to positions of the measurement points of the large-sized substrate, and then are respectively fixed at the particular positions in the groove 114 by using a heat resistant adhesive tape, such that the sampling substrate sheets 400 will not fall off from the groove 114 when overturning the measurement tool, even if in a high temperature environment. As shown in FIG. 2, after fixing the sampling substrate sheets 400 in place, the measurement tool 100 is overturned and placed on the frame of the mask 300, particularly, such that ends of the support part 120 are connected onto the frame of the mask 300, while the upper surface of the measurement part 210 is hung inside the frame of the mask 300 to face downwards. As such, thicknesses of evaporated films on a plurality of sampling substrate sheets located along a straight line on the large-sized substrate may be measured.

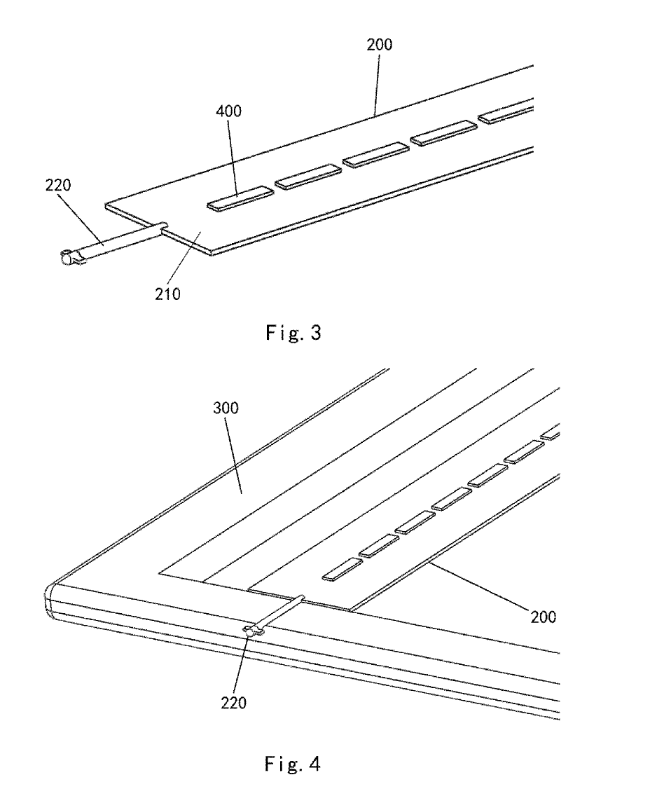

In another embodiment of the present disclosure, as shown in FIG. 3, the support part 220 of the measurement tool 200 is fixed at an intermediate position between two ends of the measurement part, instead of being provided on the lower surface of the measurement part 220, and meanwhile the support part 220 is in form of a shaft 220, such that the measurement part 210 of the measurement tool 200 can be rotatable about the shaft 220 when connected onto the frame of the mask 300. Correspondingly, a groove may be also provided at a position, where the support part 220 is to be placed, on the frame of the mask 300, for receiving the support part 220.

Since the support part 220 of the measurement tool 200 is provided at the two ends of the measurement part 210, rather than on the lower surface of the measurement part 210, it can be envisaged that graduations may be also provided on lower surface of the measurement part 210, such that sampling substrate sheets may be arranged on the upper and lower surfaces alongside the graduations on the upper and lower surfaces respectively, thereby sampling substrate sheets on the upper and lower surfaces of the measurement part 210 can be subject to film evaporation without interfering with each other because the measurement part 210 is rotatable about the shaft-shaped support part 220; in other words, the measurement part 210 may be subject to two similar or different film evaporation processes, such that a layer of evaporated film can be formed respectively on sampling substrate sheets on the upper and lower surfaces of the measurement part, without replacing the measurement part 200. This is very convenient for measurement of the large-sized substrate provided with many layers of evaporated films because exhausting work, such as repetitive replacements and arrangements of the measurement tool, may be omitted. Similarly, the measurement part of the measurement tool may be formed in a shape of a triangular prism, graduations may be distributed on side surfaces of the triangular prism in a axial direction of the triangular prism, and sampling substrate sheets are arranged alongside the graduations, thereby the times by which the measurement tool may be subject to film evaporation can be further increased. At the same time, the shape of the measurement part needs to be designed such that when film evaporation is performed on a sampling substrate sheet arranged one measurement surface at a time, a undesired evaporated film would not formed on a sampling substrate sheet arranged on other measurement surface, which otherwise would adversely affect measurement of the evaporated film of the sampling substrate sheet on the other measurement surface.

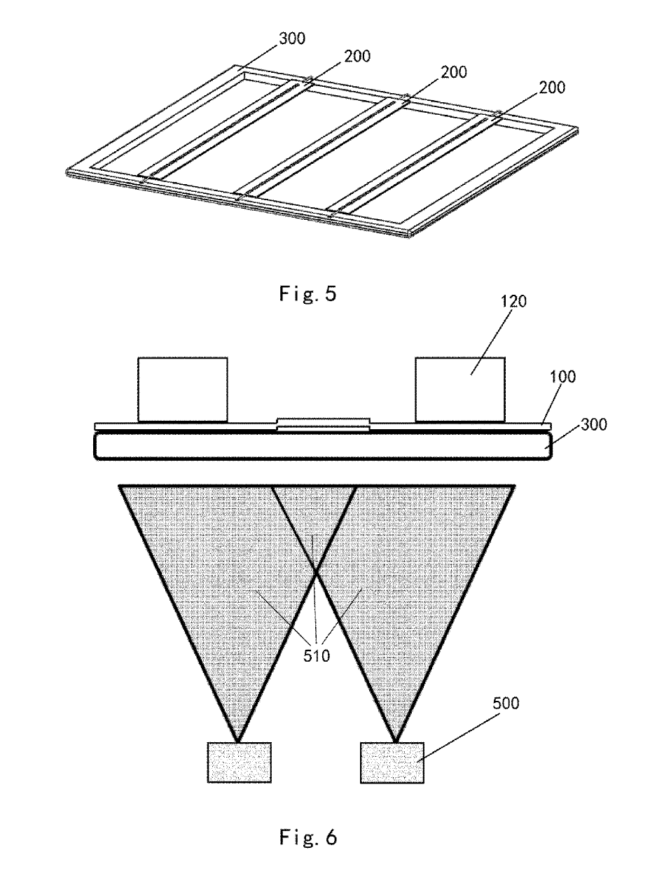

In one embodiment, a plurality of such measurement tools 200 may be used at one time, as shown in FIG. 5, such that the plurality of the measurement tools 200 carrying sampling substrate sheets thereon are arranged side by side on the frame of the mask 300, thereby thicknesses of evaporated films at different measurement points on a plurality of straight lines located at different positions on the large-sized substrate may be measured.

According to the general inventive concept of the present disclosure, there is further provided a method of measuring a thickness of an evaporated film of a large-sized substrate by using the above-described measurement tool, and the method comprises steps of: fixing at least one sampling substrate sheet at a prescribed position on the measurement surface of the measurement part according to the graduations of the measurement part, the prescribed position corresponding to a position of a measurement point of the large-sized substrate; placing the measurement part carrying thereon a sampling substrate sheet on an inner side of the frame of the mask through the support part, then placing the mask carrying thereon the measurement part within a film formation region of an evaporation source of a film evaporation apparatus, such that the sampling substrate sheet on at least one measurement surface of the measurement part faces the evaporation source so as to be evaporated with a film by the evaporation source; and after evaporating the film, taking off the measurement tool, removing the sampling substrate sheet from the measurement part, and measuring the thickness of the evaporated film of the sampling substrate sheet, thereby obtaining the thickness of the evaporated film of the large-sized substrate at the measurement point.

FIG. 6 shows an embodiment of a measurement method according to the present disclosure. In the method, the measurement tool 100 carrying thereon the sampling substrate sheet 400 is firstly connected onto the frame of the mask 300, then the mask 300 connected thereon with the measurement tool 100 is placed within a film formation region 510 above an evaporation source 500 of a film evaporation apparatus, such that the sampling substrate sheet 400 on the measurement part 110 is allowed to face the evaporation source 500 so as to be evaporated with a film by the evaporation source; after finishing film evaporation, the measurement tool 100 is taken off and the heat resistant adhesive tape is removed, such that the sampling substrate sheet 400 is removed from the measurement part, thereby the thickness of the evaporated film of the sampling substrate sheet 400 is measured, and a result of the measurement is the thickness of the evaporated film at a corresponding measurement point on the large-sized substrate.

According to another embodiment of a measurement method of the present disclosure, the mask, on which the measurement tool 200 has been arranged with at least one sampling substrate sheet being arranged at a position of the measurement tool corresponding to the measurement point of the large-sized substrate, is placed within film formation region 510 above the evaporation source 500 of the film evaporation apparatus such that film evaporation is made, as shown in FIG. 6. When many layers of films are to be evaporated on the large-sized substrate, respective layers of evaporated films need to be measured at measurement points; in such a case, the measurement tool on the mask needs not to be replaced, it is only required to turn over the measurement surface of the measurement tool on the mask for next film evaporation, for which the evaporation source may be changed as the kind of the film to be evaporated film varies, such that a different measurement surface faces a same or different evaporation source, thereby continuing film evaporation.

The measurement tool and the measurement method according to embodiments of the present disclosure enable sizes of all tools associated with measurement to be greatly reduced, which facilitates operation of a person, reduces rejection rate of sample and improves measurement efficiency.

Further, with the measurement tool and the measurement method according to embodiments of the present disclosure, there is no need to use any expensive and brittle large-sized substrate as a sample, thereby greatly reducing measurement cost, especially in case of measurements of thicknesses of a plurality of layers of evaporated films.

If a large-sized substrate is used as a sample for film evaporation, the measurement is time-consuming because uniformity of distribution of film thickness needs to be achieved, while the measurement tool and the measurement method according to embodiments of the present disclosure only utilize a series of sampling substrate sheets arranged in a row or column, which can provide a much flexible measurement of a single row or column, thereby saving measurement time.

The measurement tool according to embodiments of the present disclosure may be utilized in group, and may fix thereon a plurality of sampling substrate sheets at a time as it owns a plurality of measurement surfaces, such that a plurality of evaporation sources may be used for many times of film evaporation, without replacing the measurement tool or the sampling substrate sheet during a gap between two times of film evaporation.

Objects, technique solutions and advantageous effects of the present disclosure have been described in detail in the above exemplary embodiments. It should be understood that the above embodiments are merely exemplary embodiments of the present disclosure and are not intended to limit the present disclosure. Various changes, equivalents or modifications that are made within principle and spirit of the present disclosure also fall within the scopes of the present invention.

It is noted that terms such as “comprise”, “comprising” and the like do not exclude other element(s) or step(s), and wordings such as “an”, “a”, “one” and the like do not exclude plural. In addition, any reference numeral in the claims should not be interpreted as being limitative to the scopes of the present invention.

1. A measurement tool for measuring a thickness of an evaporated film of a large-sized substrate, the measurement tool comprising:
a measurement part, having at least one measurement surface onto which at least one sampling substrate sheet is positionable and fixable; and
a support part connected with the measurement part and configured to be supportable on an edge frame of a mask so as to place the measurement part on an inner side of the edge frame of the mask through the support part.

2. The measurement tool according to claim 1, wherein the at least one measurement surface has graduations configured to indicate a position of the at least one sampling substrate sheet on the at least one measurement surface, the position of the at least one sampling substrate sheet on the at least one measurement surface corresponding to a position of a measurement point on the large-sized substrate.

3. The measurement tool according to claim 2, wherein the measurement part comprises a rectangular sheet body, an upper surface and/or a lower surface of the sheet body forms the at least one measurement surface, and the graduations are distributed on the at least one measurement surface in a length direction of the measurement part, such that the at least one sampling substrate sheet is allowed to be distributed and arranged alongside the graduations.

4. The measurement tool according to claim 2, wherein the measurement part is in a shape of a triangular prism, a side surface of the triangular prism forms the at least one measurement surface, and the graduations are distributed on the at least one measurement surface in an axial direction of the triangular prism, such that the at least one sampling substrate sheet is allowed to be distributed and arranged alongside the graduations.

5. The measurement tool according to claim 2, wherein the measurement part is provided with a groove located alongside the graduations and configured to receive the at least one sampling substrate sheet.

6. The measurement tool according to claim 1, wherein the measurement part is made of aluminum.

7. The measurement tool according to claim 3, wherein the support part has an elongated shape, is fixed on the upper surface or the lower surface of the measurement part, and has a length larger than lengths of the measurement part and the large-sized substrate.

8. The measurement tool according to claim 7, wherein the support part comprises two elongated support bodies connected to the upper surface or the lower surface of the measurement part through an adhesive or screw connection.

9. The measurement tool according to claim 3, wherein the support part is fixed on two ends of the measurement part and is configured to be rotatably connected onto the edge frame of the mask.

10. A method of measuring a thickness of an evaporated film of a large-sized substrate by using the measurement tool of claim 2, the method comprising steps of:
fixing at least one sampling substrate sheet at a prescribed position on the measurement surface of the measurement part according to the graduations of the measurement part, the prescribed position corresponding to a position of a measurement point of the large-sized substrate,
placing the measurement part carrying thereon a sampling substrate sheet on an inner side of the frame of the mask through the support part, then placing the mask carrying thereon the measurement part within a film formation region of an evaporation source of a film evaporation apparatus, such that the sampling substrate sheet on at least one measurement surface of the measurement part faces the evaporation source so as to be evaporated with a film by the evaporation source, and
after evaporating the film, taking off the measurement tool, removing the sampling substrate sheet from the measurement part, and measuring the thickness of the evaporated film of the sampling substrate sheet, thereby obtaining the thickness of the evaporated film of the large-sized substrate at the measurement point.

11. The method according to claim 10, wherein the step of evaporating the film onto the sampling substrate sheet comprises: after evaporating the film onto the sampling substrate sheet which is located on one measurement surface of the measurement part, rotating the measurement part so as for enabling another measurement surface to face the evaporation source, and evaporating a film onto the sampling substrate sheet which is located on the another measurement surface.

12. The measurement tool according to claim 5, wherein the support part has an elongated shape, is fixed on the upper surface or the lower surface of the measurement part, and has a length larger than lengths of the measurement part and the large-sized substrate.

13. The measurement tool according to claim 12, wherein the support part comprises two elongated support bodies connected to the upper surface or the lower surface of the measurement part through an adhesive or screw connection.

14. The measurement tool according to claim 4, wherein the support part is fixed on two ends of the measurement part and is configured to be rotatably connected onto the frame of the mask.

15. The measurement tool according to claim 5, wherein the support part is fixed on two ends of the measurement part and is configured to be rotatably connected onto the frame of the mask.

16. The method according to claim 10, wherein, in the measurement tool, the measurement part comprises a rectangular sheet body, an upper surface and/or a lower surface of the sheet body forms the at least one measurement surface, and the graduations are distributed on the at least one measurement surface in a length direction of the measurement part, such that the at least one sampling substrate sheet is allowed to be distributed and arranged alongside the graduations.

17. The method according to claim 16, wherein, in the measurement tool, the support part has an elongated shape, is fixed on the upper surface or the lower surface of the measurement part, and has a length larger than lengths of the measurement part and the large-sized substrate.

18. The method according to claim 17, wherein, in the measurement tool, the support part comprises two elongated support bodies connected to the upper surface or the lower surface of the measurement part through an adhesive or screw connection.

19. The method according to claim 10, wherein, in the measurement tool, the measurement part is in a shape of a triangular prism, a side surface of the triangular prism forms the at least one measurement surface, and the graduations are distributed on the at least one measurement
surface in an axial direction of the triangular prism, such that the at least one sampling substrate sheet is allowed to be distributed and arranged alongside the graduations.

20. The method according to claim 10, wherein, in the measurement tool, the measurement part is provided with a groove located alongside the graduations and configured to receive the at least one sampling substrate sheet; the measurement part is made of aluminum; and, the support part is fixed on two ends of the measurement part and is configured to be rotatably connected onto the frame of the mask.
